(19) United States
(12) Patent Application Publication
(10) Pub. No.: US 2006/0138597 A1
(43) Pub. Date: Jun. 29, 2006

(54) Combined high reliability contact metal/ ballast resistor/ bypass capacitor structure for power transistors

(76) Inventor: David A. Johnson, Colorado Springs, CO (US)

Correspondence Address: David A. Johnson, 7945 Ruststone Ct., Colorado Springs, CO, 80919, US

(21) Appl. No.: 11/021,676

(22) Filed: Dec. 24, 2004

(51) Int. Cl. H01L 27/082

(52) U.S. Cl. 257/580

(57) ABSTRACT

A structure with the combined benefits of a highly reliable ohmic contact, ballast resistor, and ballast resistor bypass capacitor is provided. The benefit of these three features is combined into a single metal-semiconductor contact offering a reduction in space utilization, and complexity normally present in ballast networks associated with power devices.

### CROSS-REFERENCE TO RELATED APPLICATIONS

Application number 10801431, Integrated anneal cap/ion implant mask/trench isolation structure for III-V devices. Referenced in detailed description section of this application.

### STATEMENT REGARDING FEDERALLY SPONSORED RESEARCH OR DEVELOPMENT

This Invention was not conceived, constructed, or tested during the performance of a government contract.

### REFERENCE TO SEQUENCE LISTING, A TABLE, OR A COMPUTER PROGRAM LISTING COMPACT DISK APPENDIX

Not Applicable

### BACKGROUND OF THE INVENTION

1. Field of Invention

The present invention relates to semiconductor devices, such as power bipolar transistors, and power field effect transistors.

2. Description of the Prior Art

Transistors used in power applications rely on ballast resistors to mitigate effects such as thermal run-away and current collapse. In bipolar junction transistors, ballast resistors are placed in series with either the emitter, base, and in some special circumstances, the collector, of each interdigitated finger of the transistor. Examples of ballast resistors are given in U.S. Pat. Nos. 3,936,863; 4,231,059; 5,053,847; 5,444,292; 4,656,496; 5,821,602; 6,130,471; 6,236,071; 5,374,844. To mitigate the side-effect of degraded efficiency caused by the ballast resistor, a bypass capacitor is placed in parallel with the ballast resistor. This way the effect of the ballast resistor is not seen in the small signal view of the circuit, but its effect is still seen by bias currents. The introduction of ballast resistors and bypass capacitors seen in U.S. Pat. Nos. 5,841,184; 5,821,602; 5,321,279; not only consumes additional space on the associated wafer, but also adds complexity to the part.

U.S. Pat. Nos. 6,768,140; 6,611,008; 6,410,945; 6,271,098; 6,043,520; 6,025,615; 5,721,437 utilize a resistive layer below the emitter metal to integrate an emitter ballast resistor. If the resistive layer is epitaxially grown along with the other starting epitaxial layers, it is limited for practical purposes to the top electrode in the epitaxial stack, usually the emitter. If the layer is an epitaxial overgrowth, then it is very expensive to execute. Less expensive films do not offer sufficient ballast resistance for many applications. In any of the above cases, a bypass capacitor would require additional wafer space and complexity.

U.S. Pat. No. 6,455,919 achieves an integrated base ballast resistor and capacitor, but it requires a special dielectric layer between the extrinsic base and collector semiconductor layers. It also does not provide any reliability advantages for compound semiconductor contacts.

High efficient heterojunction bipolar transistors (HBTs) are typically made using III-V semiconductors. As described on p454-455 of S. K. Ghandhi, “VLSI Fabrication Principles”, Wiley, N.Y., 1983; ohmic contacts to these semiconductors are typically made with metals that alloy with the associated semiconductor. This type of ohmic contact is not typically thermally stable, and exhibits both ohmic contact resistance degradation, and underlying semiconductor degradation over time. Ohmic contacts to III-V semiconductors that have utilized thermally stable metals, and especially etchable thermally stable metals, have required special semiconductor contact layers below the metal. This results in either a compromise to an otherwise optimized semiconductor layer, or the requirement of an expensive epitaxial overgrowth layer. In the case of an ohmic contact to the base region of an HBT, any compromise in the base layer for better ohmic contact will have a significant impact on the final performance of the device.

### BRIEF SUMMARY OF THE INVENTION

A structure with the combined benefits of a highly reliable ohmic contact, ballast resistor, and ballast resistor bypass capacitor, is built by depositing a thermally stable metal (12) on a critically doped semiconductor (11) as shown in FIG. 1. The resulting contact results in a linear, or near-linear current-voltage relationship at low frequencies, and a linear, and much lower resistance behavior at higher frequencies. The equivalent circuit is shown in FIG. 2, where the resistor element (21) represents the tunneling resistance of the depletion layer (13), and the capacitor element (22) represents the capacitance of the depletion layer (13). When this structure is applied to the base contacts of a four finger interdigitated bipolar transistor, the equivalent circuit is shown in FIG. 3. As one finger of the transistor heats-up, and the bias current starts to increase, the increased voltage drop across the ballast resistor associated with that finger keeps the current from increasing further. This known advantage of ballast resistors, along with the performance advantage of a bypass capacitor, are achieved with the present invention without the usual disadvantage of extra space and complexity required by conventional resistor and capacitor structures. No additional space or process steps are required for a transistor with this structure than one omitting the ballast resistor and bypass capacitor elements altogether.

Since the base contact metal is thermally stable, it results in a reliable ohmic contact, and reliable associated bipolar junction transistor. Further, because alloying with the semiconductor is not required nor desired, easily etched metals may be used for this application, resulting in a lower defect density process than other metals patterned by less favorable means.

### BRIEF DESCRIPTION OF THE SEVERAL VIEWS OF THE DRAWING

FIG. 1 depicts, in cross-sectional view, the structure of the invention.

FIG. 2 illustrates the equivalent circuit of the invention.

FIG. 3 illustrates the equivalent circuit of the invention along with an associated transistor example.

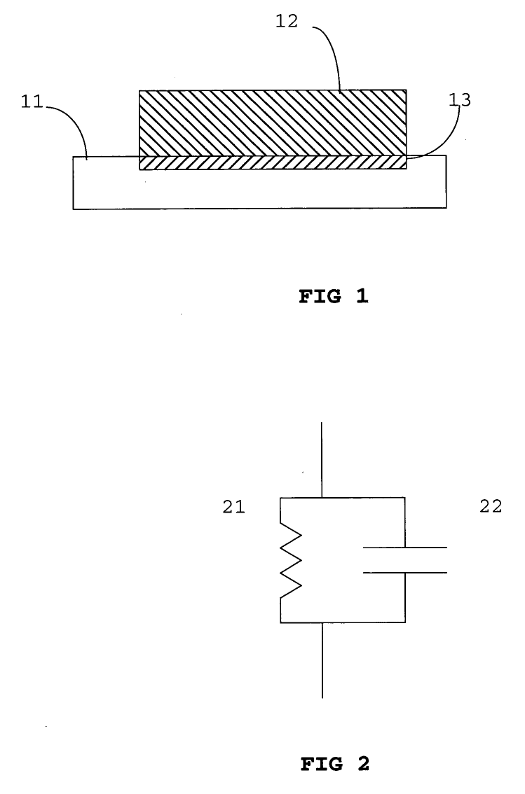

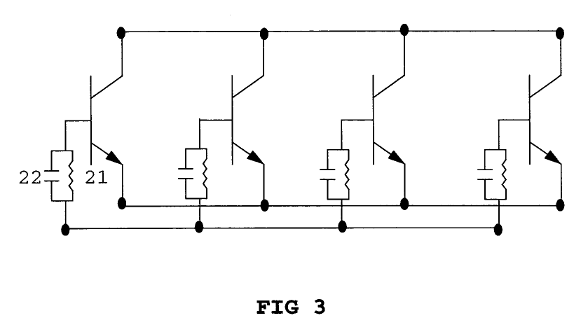

### DETAILED DESCRIPTION OF THE INVENTION

While the description below is specifically directed to gallium arsenide (GaAs) devices, it will be appreciated that other power devices will similarly benefit from the teachings of the invention.

### First Embodiment

N-type sub-collector, n-type collector, p-type base, n-type emitter, and n-type emitter contact layers are formed on a semi-insulating GaAs wafer by conventional means, with the constraint that the top 50 to 200A of the base layer is doped between 8×1018 and 8×1019/cm3 p-type.

The wafer is then processed to form an interdigitated npn HBT by using conventional means, or similarly, using the structure described in the patent application titled “Integrated anneal cap/ion implant mask/trench isolation structure for III-V devices (application number 10801431), until the base semiconductor is exposed.

The surface of the semiconductor is cleaned with an acid such as HCl, then tungsten is then deposited on the entire wafer using physical vapor deposition.

Photoresist is patterned over the tungsten using methods well known in the art.

The tungsten is etched using a fluorine-containing plasma into a pattern defined by the photoresist.

The photoresist is removed by methods well known in the art.

Optionally, a dielectric may be deposited over the tungsten, and annealed at an elevated temperature to sinter the contact. The temperature required for contact sinter must be high enough for the tungsten to absorb interfacial oxide between it and the semiconductor, but not high enough to damage the semiconductor (400-700 C).

The result is an npn HBT with a base ballast resistor, and a bypass capacitor built-in to the base contact structure.

### Second Embodiment

A interdigitated power n-channel field effect transistor is fabricated on GaAs up to the point of source contact by conventional means, except the source region is doped between 8×1018 and 8'1019/cm3 n-type.

The surface of the semiconductor is cleaned with an acid such as HCl, then tungsten is deposited on the entire wafer using physical vapor deposition.

Photoresist is patterned over the tungsten using methods well known in the art.

The tungsten is etched using a fluorine-containing plasma into a pattern defined by the photoresist.

The photoresist is removed by methods well known in the art.

Optionally, a dielectric may be deposited over the newly patterned source contact metal, and annealed at an elevated temperature to sinter the contact. The temperature required for contact sinter must be high enough for the tungsten to absorb interfacial oxide between it and the semiconductor, but not high enough to damage the semiconductor (400-700 C).

The result is a power n-channel field effect transistor with a source ballast resistor, and bypass capacitor built-in to the source contact structure.

I claim:

1. A metal-semiconductor contact structure with the combined benefits of a highly reliable ohmic contact, ballast resistor, and ballast resistor bypass capacitor.

2. A power transistor utilizing said metal-semiconductor contact structure of claim 1 in a base, emitter, collector, gate, source or drain ballast configuration.

3. The power transistor of claim 2, where said transistor is a bipolar junction transistor.

4. The power transistor of claim 2, where said transistor is a field effect transistor.

5. The bipolar junction transistor of claim 3, where said bipolar junction transistor is a heterojunction bipolar junction transistor (HBT).

6. The HBT of claim 5, where said HBT semiconductors consist of GaAs, and similar lattice matched III-V semiconductors.

7. The HBT of claim 5, where said HBT semiconductors consist of InP, and similar lattice matched III-V semiconductors.

8. The HBT of claim 5, where said HBT semiconductors consist of GaAs, and similar strained semiconductor layers.

9. The HBT of claim 5, where said HBT semiconductors consist of InP, and similar strained semiconductors layers.

10. The bipolar junction transistor of claim 3, where the semiconductor in said transistor consists essentially of silicon.

11. The bipolar junction transistor of claim 3, where the semiconductor in said transistor consists essentially of silicon and germanium.

12. The metal-semiconductor contact structure of claim 1, where said contact consists of a thermally stable metal, and a critically doped semiconductor.

13. The critically doped semiconductor of claim 12, where the resulting depletion region in said semiconductor is thin enough to form a capacitor that is bypassed at the operating frequency, but thick enough to add effective ballast tunneling resistance at D.C. bias.

14. The critically doped semiconductor of claim 12, where the resulting depletion region in said semiconductor is thin enough to allow carriers to tunnel, and form a linear contact.

15. The metal-semiconductor contact structure of claim 12, where said thermally stable metal consists essentially of tungsten.

16. The metal-semiconductor contact structure of claim 12, where said thermally stable metal consists essentially of tungsten and nitrogen.

17. The metal-semiconductor contact structure of claim 12, where said thermally stable metal consists essentially of molybdenum.

18. The metal-semiconductor contact structure of claim 12, where said thermally stable metal consists essentially of chromium.

19. The metal-semiconductor contact structure of claim 12, where said thermally stable metal consists of a combination of tungsten, molybdenum, chromium, titanium, tantalum, and nitrogen.

20. The critically doped semiconductor of claim 12, where doping level of said semiconductor is between 8×1018 and 8×1019/cm3.
